(19) United States
(12) Patent Application Publication
(10) Pub. No.: US 2017/0355918 A1
(43) Pub. Date: Dec. 14, 2017

(54) SYSTEM FOR, METHOD OF, AND THE RESULTING PRODUCT OF THE PRODUCTION OF FUEL GAS, HEAT AND ELECTRICITY

(71) Applicant: Francesco Li Gregni, San Giovannia Gremini (IT)

(72) Inventor: Francesco Li Gregni, San Giovannia Gremini (IT)

(73) Assignee: Syntactic Dream Energy, LLC, Freehold, NJ (US)

(21) Appl. No.: 15/176,621

(22) Filed: Jun. 8, 2016

(51) Int. Cl. C10L 3/00; C10K 3/06; C25B 15/02; C25B 1/04; C10K 3/02; H01L 35/02

(52) U.S. Cl. CPC C10L 3/00; C10K 3/02; H01L 35/02; C25B 15/02; C25B 1/04; C10K 3/06; C10L 2290/24; C10L 2270/04; C10L 2270/10; C10L 2290/58; C10L 2290/38; C10L 2290/08

(57) ABSTRACT

Traditional residential and industrial furnace systems convert the chemical energy of liquid and gas fuels into thermal energy and, in some earlier applications, also into electric energy. This process is driven by a burner specifically designed and built. Often these systems operate at high temperatures, high pressures and relatively lower efficiency levels. The field of present invention generally relates to furnaces that combine the fuel production to the both thermal either electrical energy production. More particularly, the present invention produces a combustible gas that, within the internal workings of the present invention, and can efficiently be burned without the production of high levels of pollutants, at relatively lower temperatures and pressures. The foregoing characteristics, along with the limited size of the elements needed to practice the present invention, make it conducive for use as and in connection with, among other things, residential furnaces and other heating systems, including, for example, heat exchangers and residential hot water tanks. In short, the present invention involves the production of a combustible fuel gas, thermal and electric energy. This production is accomplished through the interconnected use of water electrolysis, catalysts, storage means, regulation, and mean of reusing materials to increase production efficiencies.

### FIELD OF THE INVENTION

The present invention relates to the production of a combustible gas. Heat and electricity can also be produced by the practice of the present invention. The system and method involves use of primary gases in a thermochemical-catalyzed reaction. The primary gases are produced by water electrolysis. The resulting combustible gas has physical characteristics that allow the product to be produced, stored, transported and use cost effectively and safely. Further, the present invention relates also to the use of the combustible gas (i.e., the product of the process) as fuel for electricity and thermal energy production for domestic and industrial purposes, as fuel for transportation applications, and in connection with renewable energy storage.

### BACKGROUND OF THE INVENTION

The systems and methods employed to produce heat, electricity and power have improved as the consumption of all three of these and other expressions of energy have increased. Some of this energy is created following the production of combustible gas. Such gas is, at times, produced for the generation of thermal and electric energy in stationary devices, for applications in the transportation field, for the production of heat, air and hot water and electric energy, even from renewable source, or for a combination of the foregoing. Particular examples include the uses of furnaces for the production of air and hot water. The production of combustible gas has also been vital for the sectors of cogeneration of electricity, renewable energy storage, and thermal energy and for use as fuels for transport means and propelled in general.

In general, existing furnaces generate heat by a gaseous, liquid or solid fuel that is provided from either a supply network (e.g., piping built to transport natural gas to residences) or suitably sized tanks and storage spaces that house the fuel(s) (e.g., propane tanks storing fuel for residential power outage situations). As a result, such furnaces are typically not operated in the places where (A) these fuels are not available via a supply network and (B) the space for sufficient storage tanks is limited or nonexistent. Moreover, such furnaces do not typically generate by themselves the combustible gas or other combustible liquids or solids.

Another aspect of this field is the need to operate the equipment used to produce combustible gases at high temperatures, under high pressure, or both. For example, reference is made to the process discussed in US Patent Application Nos. US20160107952A1, US20160053388A1, and US20140000157A1, and U.S. Pat. No. 8,506,910B2 and U.S. Pat. No. 7,989,507B2. Each of the following references teaches the use of high temperatures and high pressures in the creation of their respective products. These productions parameters, however, inherently limited the suitability of the disclosed processes in many residential settings and in smaller spaces (e.g., as part of the power plant of a motor vehicle).

Another aspect of this field is the nature of the combustible gases. Some of the processes employed to produce combustible gases create a resulting product that is highly combustible and more unstable. Such gases are difficult and expensive to transport, present multiple safety concerns regarding their storage, and are practical for use in unsophisticated business environments, by residences and to power motor vehicles.

The present invention, addressing the foregoing, consists of embodiments of systems and methods that can intake fuel that is originally sourced from a supply network, a small storage tank, produced at least in part of the systems and methods themselves, or a combination of the foregoing. The same systems and methods can be operated at temperatures and pressures that are suitable for residences and other locations (e.g., motor vehicles), with less concern despite the potential residential setting and the smaller size of the space. The resulting product of the various embodiments of the systems and methods that is suitable for cost-efficient and safe transport, storage and use.

### BRIEF SUMMARY OF THE INVENTION

The present invention comprises a series of systems, methods and products in the field of fuel. In one embodiment of the process, through which a combustible gas is efficiently (>80% efficiency) produced (without producing polluting emissions from fossil hydrocarbons), the steps include (A) producing primary gases by water electrolysis, (B) mixing and filtering such primary gases, (C) internally producing CO₂ gas, (D), storing such CO₂ gas, (E) mixing the filtered primary gases with the previously produced CO₂ gas in a catalytic reaction at a temperature above 15° C. and below 500° C. and at a pressure higher than 1 bar and lower than 10 bar wherein the gas mixture is conveyed over the surface of a desired catalyst, (F) releasing undesired/unneeded molecules, (G) collecting the final gas formulation, having the desired chemical and physical properties, (H) recovering water produced through the process, and (I) recovering any residual CO₂ gas for use in the process in combination with the produced/stored CO₂ gas.

In one embodiment of the system, through which combustible gas with the same properties is produced with the same efficiencies, the elements include (A) a means of producing primary gases through water electrolysis, (B) a means of mixing and filtering such primary gases, (C) a means of producing CO₂ gas, (D) storing such CO₂ gas, (E) a means of mixing the filtered primary gases with the previously produced CO₂ gas in a catalytic reaction at a temperature above 15° C. and below 500° C. and at a pressure higher than 1 bar and lower than 10 bar, (F) a means of conveying the primary gas/CO₂/CO gas mixture over the surface of a desired catalyst, (G) a means of releasing undesired/unneeded molecules, (H) a means of collecting the final gas formulation with the desired chemical properties, (I) a means of recovering water produced through the process, and (J) a means of recovering any residual CO₂ gas for use in the process in combination with the produced/stored CO₂ gas.

A third aspect of the present invention is a combustible gas, produced through the use of one or more of the systems and/or methods described herein, that is suitable for cost-efficient and safe transport, storage and use.

### BRIEF DESCRIPTION OF THE DRAWINGS

The components and the advantages related to the present invention will be better depicted by referring to the drawings, in which:

FIG. 1 is a block diagram of a system for gas production integrated with a furnace operating in cogeneration mode with high efficiency and reduced emissions.

FIG. 2 is a functional diagram of a system for gas production with integrated furnace operating in cogeneration mode with high efficiency and low emissions.

FIG. 3 is a functional diagram of the control system of a gas production system integrated with the furnace operating in cogeneration mode with high efficiency and reduced emissions.

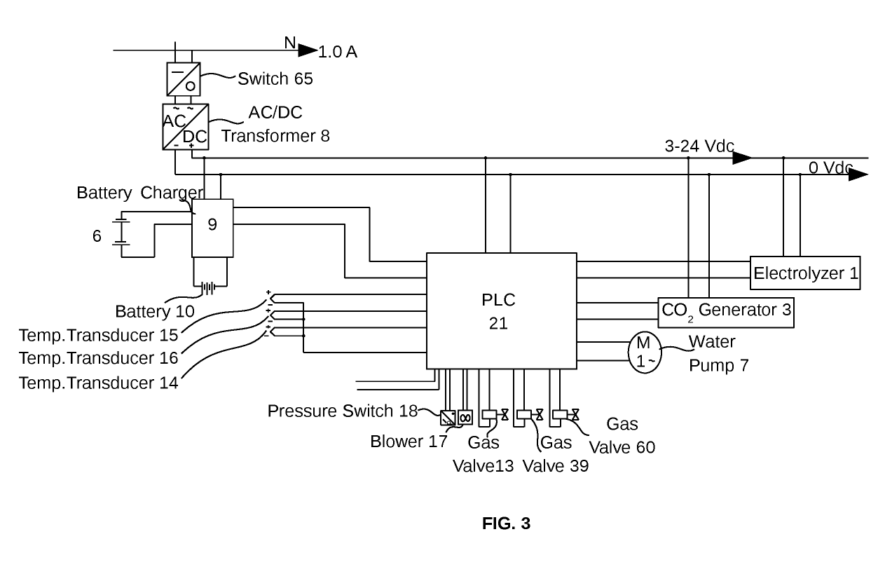

### DESCRIPTION OF THE PREFERRED EMBODIMENTS

The present invention provides the fuel used for the generation of both electricity and heat, as a fuel for cogeneration, renewable energy storage, transportation, and potentially a multitude of other purposes. As known by those of ordinary skill in the art, the distributed generation of fuels, electricity and heat is an efficient and clean solution for the environment due, in part, to the high technical efficiency of the applicable system. Another advantage is represented by distributed cogeneration of heat and power that can bring the overall performance of the applicable system to exceed, for example, eighty percent (80%). Another advantage in certain system is the absence of polluting emissions from fossil hydrocarbons. In fact, the combustion of fossil hydrocarbons forms polluting gas species such as, for example, NOₓ, CO, HC, SOₓ, PM10, and PM5. Moreover, from fossil sources are produced substances altering the CO₂ balance and the other atmospheric gases.

Conversely, the present invention, which is herein described, uses water that is decomposed into molecules as H₂, O₂ and HO. These molecules are reacted with CO₂, generated from a different water stream. The CO₂ is also recovered from the exhaust gases and/or sourced from another CO₂ emitting source. The primary reaction, which takes place in the reactor in the presence of a catalyst, leads to the formation of a gas mixture that contains CH₄, CO, CO₂, H₂, and O₂. The balance of the CO₂ of the environment is not altered. There are no fossil fuels or biomasses used in the practice of the present invention, and thus no introduction of a notable amount of CO₂ SOₓ, and other harmful gases into the environment deriving from those fuels. Furthermore, the present invention does not produce any particulates since no fuels containing long chains of carbon or ashes are used. The NOx generated are in quantities far below the emissions levels from other existing technologies due to the fact that a part of the oxygen for combustion is generated with the same fuel gas, thereby reducing the amount of ambient air intake needed for the combustion.

In accordance with the present invention, and in more detail, the method of generating the fuel gas and both thermal and electrical energy includes the steps of (A) production of the initial gases, (B) mixing the initial gases and their conversion into the catalytic reactor to form the final formulation of the fuel for the end uses, (C) as desired, generating electric and/or thermal energy, and (D) when appropriate, storing the electrical energy storage and/or exchanging produced thermal energy. The system that comprises the present invention includes the elements needed to perform the steps written above. The inventive product is the result of the performance of the steps, the use of the elements, and the appropriate combination of both.

The gas generation step includes the generation of O₂, OH and H₂ gases. At roughly the same time, the CO₂ generator produces CO₂ gas, which is preferably collected in the storage embedded to the generator itself. Said O₂, OH and H₂ gases pass through the filter and are mixed with CO₂ in the catalytic reactor. One of ordinary skill in the art would know that various embodiments call for the gases to be produced at differing times and in differing locations, noting that the more critical aspect of this part of the method is the appropriate levels of and for the reaction temperature, pressure, filtering and mixing.

The catalytic reactor is preferably maintained at a temperature above 15° C. and below 500° C. The gases, which will have a pressure preferably equal to or higher than 1 bar and lower than 10 bar, are mixed and flow over and in contact with the surface of the catalyst. Said catalyst is composed of Copper, Nickel, Iron, Platinum, Ruthenium, Manganese, Molybdenum, and Cobalt or mixtures between them and these elements are deposited, in fractions, and various quantities, upon different substrates. One of ordinary skill in the art would know that the specific composition and nature of the catalyst may have more beneficial or more negative impact on the physical properties of the resulting fuel gas and other aspects of the process (e.g., the heat and/or electricity generated). Care should be given to use the catalyst that results in outputs that are the closest to those desired by the practitioner.

In the catalytic reactor, the reactions for the formation of CH₄, CO, and H₂O occur. Since such reactions and the resulting formations are incomplete, there is a continued presence of H₂ and O₂ molecules in the final gas mixture exiting from said reaction. The appropriate control of pressure and temperature of gases and the catalyst's proper composition leads to the final gas in the formulation desired.

The water produced in said reaction is preferably recovered in the feed tank of the machine. The final gas may be used for cogeneration, renewable energy storage, transportations, other applications, or a combination of applications. In the case of cogeneration of heat and power, this process could take place inside the preferred embodiment as a domestic furnace producing electricity and hot water or air. The produced heat could be used to power a thermoelectric generator that could produce electricity, and to heat water or air for domestic and industrial purposes, or for a variety of other purposes. The produced electrical energy could also be stored in the battery and/or be used for the process here depicted. In a preferred embodiment of the present invention, the gases resulting from the combustion are separated to recover the CO₂, whilst the residual gases are emitted into the atmosphere. The CO₂ recovered could thereafter be stored into the CO₂ generator.

Through the use of for example, water, electricity, materials, mechanical and electrical parts appropriately configured, the present inventive system provides the production of a gas that can be used for, for example, the generation of power and heat in the civil and industrial sectors, residences, or other venues. Conversely or in addition, the gas can be used as a fuel in the transportations sector, for renewable energy storage, and otherwise.

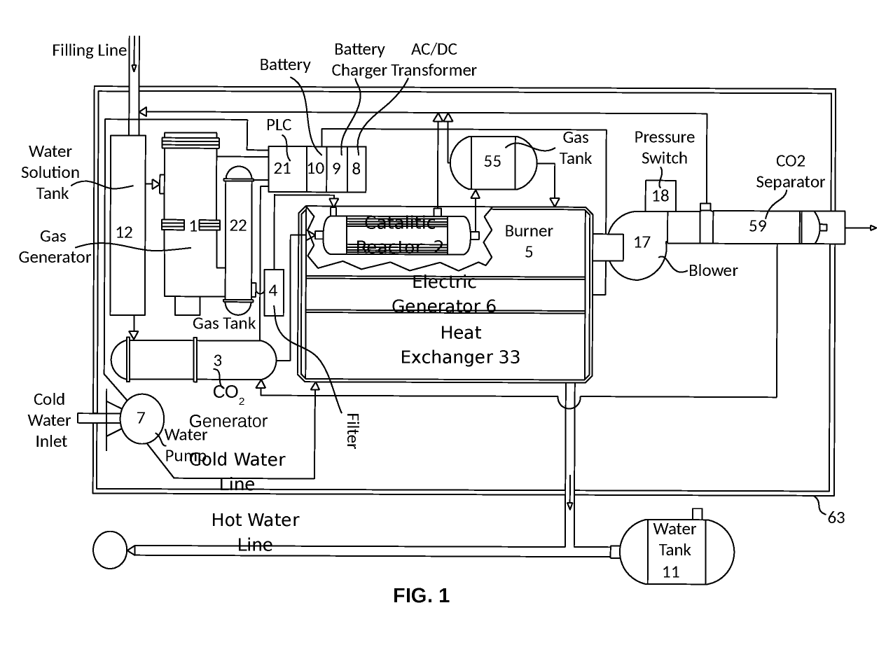

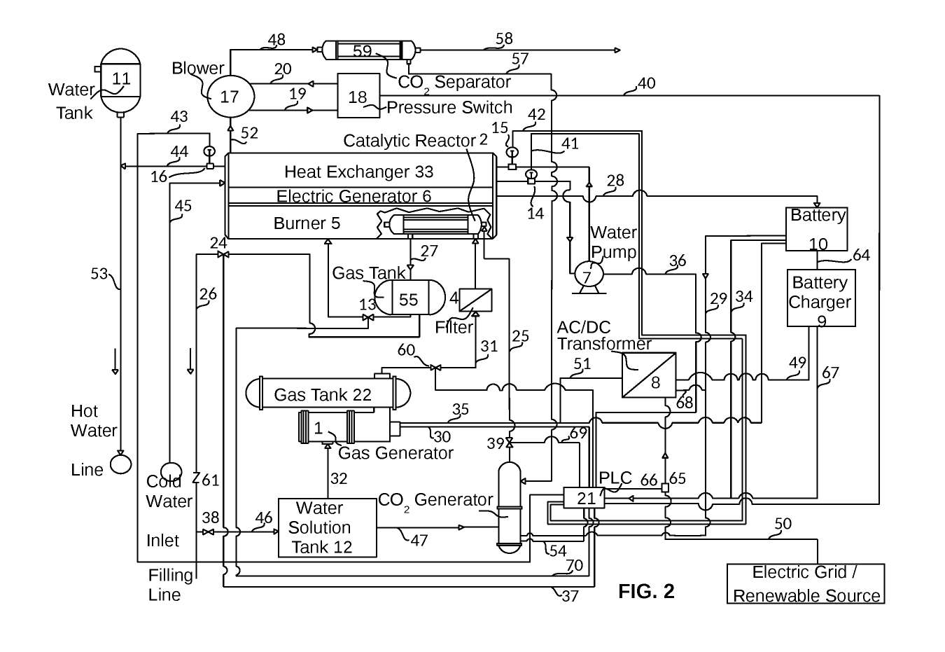

FIG. 1 shows a preferred embodiment of the present invention—realized by a furnace for the generation of heat and electricity. In this particular embodiment of the inventive system, the elements include water reservoir tank 12, electrolytic gas generator 1, gas tank 22, CO₂ generator (with embedded CO₂ buffer tank) 3, gas filter 4, catalytic reactor 2, combustion chamber 5, thermoelectric generator 6, heat exchanger 33, water circulation pump 7, electrical power supply 8, battery-charger 9, accumulator 10, programmable logic computer 21, gas reservoir tank 55, fan 17, CO₂ separator 59. FIG. 2 shows the inventive system as shown in FIG. 1 with the addition of temperature transducer 14, temperature transducer 15, temperature transducer 16, pressure transducer 18, non-return check valve 61, solenoid valve 13, regulating valve 39, controlled open/close valve 60, electric switch 65, piping, electric cables and the connection relative to said components.

In the use of the inventive system, the electric power from the national grid is used by battery charger 9 for charging the accumulator 10 and, as needed, by electrical power supply 8 to start the process. Also present is electrolytic gas generator 1, which can be filled with water or, as desired or needed, another aqueous solution and which is electrically powered by power supply 8 and controlled by programmable logic computer 21. Programmable logic computer 21 could be comprised of a variety of components and software that allow it to be used to manage various elements of the inventive system. Although the power can be adjusted as needed, the supply voltage preferably varies between 1.5V [DC] and 240V [DC], where the current varies accordingly to the voltage and the water solution composition.

In one embodiment of the present invention, battery charger 9 is connected to the power supply 8 from cable 49 and to, and controlled by, the programmable logic computer 21 through cable 67, it is used to charge accumulator 10 by means of electric cable 64. Power supply 8 is preferably connected to a national power grid through cable 50 and is used to start the process carried out by the present invention or a renewable electric energy source. The switch 65, which can be preferably connected to programmable logic computer 21 via electric cable 66, can be operated by programmable logic computer 21 to manage the connecting or disconnecting of power supply 8 from a national electric grid or a renewable electric energy source.

CO₂ generator (with embedded CO₂ buffer tank) 3 by cable 68; said system can therefore be powered by a national grid when switch 65 is closed and by the battery when switch 65 is open. At start the electrolytic gas generator 1 is filled with water or an aqueous solution and is electrically powered by power supply 8; the voltage of the electric energy varies preferably between 1.5V [DC] and 240V [DC], where the current is varied accordingly to the voltage and the water solution.

The gases produced by electrolysis are preferably composed of desirable amounts of O₂, OH and H₂. These gases are collected in gas tank 22, preferably pass through regulating valve 60, are filtered by filter 4 and then sent to catalytic reactor 2, wherein the O₂, OH and H₂ gases are mixed with CO₂ and CO gas. Said CO₂ and CO gases are produced by CO₂ generator (with embedded CO₂ buffer tank) 3, filled with water or another desired solution or set of solutions and powered by electrical power supply 8. Said CO₂ and CO gases are fed to catalytic reactor 2 through regulating valve 39.

Catalytic reactor 2 preferably operates at a temperature of or between 15° C. and 500° C. and at a pressures of or between 1 bar and 10 bar. The reaction between the H₂, O₂, CO₂ and CO takes place in the presence of a catalyst which can be made of, for example, Copper, Nickel, Iron, Platinum, Ruthenium, Manganese, Molybdenum, Cobalt, one or more mixtures of the foregoing or a different material or set of materials known to those of ordinary skill in the art. The reaction time is preferably between 1 second and 15 seconds, with a more preferred reaction time between 3 seconds and 6 seconds.

Said reaction is exothermic and produces H₂O, CH₄, CO, CO₂, H₂ and O₂, with the efficiency of the reaction preferably higher than eighty percent (80%) and below 90%. The water, formed in catalytic reactor 2 and condensed into gas reservoir tank 55, is fed back into the process, respectively, through conduit 63 and tube 26 in which is inserted non-return check valve 61. Finally, the H₂O is entered through pipe 46, which holds the regulating valve 38, in the water reservoir tank 12, then in the electrolytic gas generator 1 and in CO₂ generator (with embedded CO₂ buffer tank) 3.

The remaining gas, accumulated in gas reservoir tank 55, are introduced into combustion chamber 5, where they are burned with atmospheric air to produce heat. The flow of gas from gas reservoir tank 55 to combustion chamber 5 is controlled by safety solenoid valve 13, which is preferably connected to and actuated by programmable logic computer 21.

In one preferred embodiment of the present invention, heat is transferred to thermoelectric generator 6 and subsequently to heat exchanger 33. The thermoelectric generator 6 preferably operates between 300° C. and 95° C., producing DC electrical energy having voltage preferably in the range 13V-14V, which is sent to accumulator 10; said accumulator 10 would be preferably connected to and controlled by programmable logic computer 21. Heat exchanger 33 preferably operates at a temperature of 95° C. (on the hot side) and heats up the water coming from the heating circuit and water tank 11, with the water being pumped by water circulating pump 7, which is connected to and controlled by programmable logic computer 21.

The temperature of the water entering heat exchanger 33 is preferably detected by temperature transducer 15, while the temperature at the exit of heat exchanger 33 is detected by temperature transducer 16. Both of temperature transducers 15 and 16 are preferably connected to and controlled by programmable logic computer 21. Temperature transducer 14, connected to and controlled by programmable logic computer 21, preferably detects the temperature of the recirculating water pumped by water circulation pump 7.

In a further preferred embodiment of the present invention, the gases produced by the combustion in combustion chamber 5 are blown to CO₂ separator 59 by fan 17 connected to pressure transducer 18, which is in turn preferably connected to and controlled by programmable logic computer 21. The CO₂ recovered from combusted gases goes into the CO₂ generator (with embedded CO₂ buffer tank) 3 and is fed to the process. The remaining gases are released into the atmosphere through exhaust 58.

In another preferred embodiment of the present invention, the gas produced and accumulated in gas reservoir tank 55 is used as a fuel for transportation, for civil and industrial applications, and for similar purposes. This product is also of a physical nature that it can be stored and transport with little concern of unintended combustion and for use in renewable energy storage.

The relative propositions of the gases that mix and react in catalytic reactor 2 are carefully regulated by regulating valve 60 regarding to the H₂ and O₂ gases, and by regulating valve 39 with regarding to the CO₂ and CO gases. These valves regulate the flow of gases in order to convert a substantial portion of H₂, O₂, CO₂ and CO into CH₄ and H₂O. The reactions between CO with O₂ and between H₂ with CO₂ are exothermic and contribute to maintaining the operating temperature in a range which is preferably between 100° C. and 400° C. The weight ratio between CO₂ and H₂ is in the range from 50 to 1, for example about 44 to 2 and the atomic ratio between oxygen and carbon monoxide is in the range from 0.5 to 3, for example about 1 to 2. The atomic ratio between CO₂ and CH₄ is in the range from 0.5 to 2, the atomic ratio between H₂ and H₂O is in the range from 1 to 3. The atomic ratio between H₂ and CO₂ is between 0.5 to 4, where the atomic ratio between CO₂ and H₂O is in the range from 1 to 2. The reaction occurring into catalytic reactor 2 is exothermic and produces as a final gas mixture formed by H₂O, and CH₄, and in a smaller amount by CO, CO₂, H₂ and O₂, being the overall efficiency of the reactor and the reactions lower than 90%, but one skilled in the art would know that the efficiency could be higher if the invention can be practiced in ways to reduce the amount of the unconverted reactants. Said gases are accumulated in gas reservoir tank 55 connected to reactor 2 from pipe 27. Here the gases are cooled to a temperature below 95° C., and the H₂O is condensed. This water is recovered via conduit 63, control valve 24 and tube 26 in which non-return check valve 61 is inserted.

Finally, the H₂O is introduced into water reservoir tank 12 through pipe 46, which holds the regulating valve 38. The fuel gas accumulated in gas reservoir tank 55 is fed into combustion chamber 5, where they are burned to produce heat. The flow of gas from gas reservoir tank 55 to combustion chamber 5 is controlled by safety solenoid valve 13, which is connected to and actuated by programmable logic computer 21. In a preferred embodiment of the present invention, the heat of combustion gases is transferred to thermoelectric generator 6 and then to the heat exchanger 33. In this way, the thermoelectric generator 6 produces electricity as direct current. Said electricity is sent to accumulator 10, which is connected to and controlled by programmable logic computer 21. Heat exchanger 33 is embedded into a wall of thermoelectric generator 6, being heated with this. The heat exchanger transfers the heat to the water coming from the heating circuit and water tank 11. The water is placed in circulation by water circulation pump 7 connected to and controlled by programmable logic computer 21.

The CO₂, when recovered, is sent in CO₂ generator 3 and fed back into the process. The remaining gases are released into the atmosphere through exhaust 58. Temperature sensor 14 signals the limit temperature at which programmable logic computer 21 starts water circulation pump 7. Temperature transducer 15 signals the upper limit temperature of the water so that programmable logic computer 21 acts on the solenoid valve 13 to regulate the combustion in the combustion chamber 5. Pressure transducer 18 detects the exhaust gas pressure from the combustion chamber 5 sending the signal to programmable logic computer 21 for the regulation of the combustion.

The electricity generated by thermoelectric generator 6 charges accumulator 10. Accumulator 10 is connected to and controlled by programmable logic computer 21 in such a way that it can power the process when switch 65 is open to allow the autonomous operation of the system. Water pump 7 is controlled and operated by programmable logic computer 21. Water pump 7 is electrically supplied by a national electric grid with an external circuit to the present invention not shown here.

One of ordinary skill in the art would know that the present invention as a method could be used in lieu of or in addition to a multitude of methods with various configurations that produce gas, heat, electricity or any combination of the forgoing. In parallel, one of such skill would realize that the application of the present invention as a system could be in conjunction with or as a replacement for any number of systems that use gas, heat, electricity or any combination of the foregoing in their operations, such as, for example, internal combustion engines, gas turbines engines and prime movers, and larger furnaces. Correspondingly, the gas fuel produced through the practice of the inventive method and/or the inventive system could be use in the same fashion and ways as other combustible fuels.

What is claimed is:

1. A method of efficiently producing a combustible gas, without producing polluting emissions from fossil hydrocarbons, comprising the steps of
a) producing primary gases by water electrolysis;
b) mixing and filtering such primary gases;
c) internally producing CO₂ gas;
d) storing the produced CO₂ gas;
e) mixing the filtered primary gases with the previously produced CO₂ gas in a catalytic reaction at a temperature above 15° C. and below 500° C. and at a pressure higher than 1 bar and lower than 10 bar wherein the gas mixture is conveyed over the surface of a desired catalyst;
f) releasing undesired and unneeded molecules;
g) collecting the final gas formulation, having the desired chemical and physical properties;
h) recovering water produced through the process; and
i) recovering any residual CO₂ gas for use in the process in combination with the produced and stored CO₂ gas.

2. The method of claim 1 wherein the primary gases produced through such water electrolysis are H₂ and O₂ gases and such gases are produced using a voltage between 1V [DC] and 240V [Dc].

3. The method of claim 1 wherein the CO₂ gas are produced simultaneously in a generator using a voltage between 1V [DC] and 240V [Dc].

4. The method of claim 1 wherein the desired catalyst is at least one of the group of elements including Copper, Nickel, Iron, Platinum, Ruthenium, Manganese, Molybdenum, and Cobalt.

5. The method of claim 4 wherein in the desired catalyst is a combination of such elements.

6. The method of claim 1 wherein the catalytic reaction produces a hot gas flow composed of CH₄ and H₂ CO₂ and H₂O.

7. The method of claim 7 wherein the gases are accumulated in a tank in which the H₂O is condensed.

8. The method of claim 1 wherein the steps are controlled through the use of a programmable logic computer.

9. The method of claim 1 wherein the electrolysis uses a solution made primarily of water.

10. The method of claim 1 wherein CO gas is internally produced prior the mixing of the filtered primary gases with the previously produced CO₂ and such CO is also mixed with such filter primary gases.

11. The method of claim 10, wherein the weight ratio between CO₂ and H₂ is in the range from 50 to 1 and the atomic ratio between O₂ and CO is in the range from 0.5 to 3.

12. The method of claim 1 wherein the final gas formulation is burned to produce heat.

13. The method of claim 12 wherein the heat produced is used to produce electric energy by a thermoelectric generator that operates between the temperatures of 300° C. and 95° C.

14. The method of claim 13 wherein such produced electric energy is in the form of a direct current that can be stored in a battery.

15. The method of claim 12 wherein exhaust gases produced by the burning of such gas are blown by a fan for the separation of CO₂.

16. The method of claim 15 wherein the separated CO₂ is recovered for reuse in the process.

17. The method of claim 13 wherein the produced heat is conducted from the cold side of the thermoelectric generator is transferred to a heat exchanger for heating desired elements

18. The method of claim 13 wherein the desired element is air.

19. The method of claim 17 wherein the desired element is water.

20. The method of claim 17 wherein the desired element, when heat, is used for industrial purposes.

21. The method of claim 16 wherein the desired element, when heat, is used for residential purposes.

22. The method of claim 10, wherein the catalytic reaction produces gases consisting of CH₄, CO₂, H₂ and H₂O with different mixing ratios.

23. A system, through which combustible gas can be efficiently produced, without producing polluting emissions from fossil hydrocarbons, comprising:
a) a means of producing primary gases through water electrolysis;
b) a means of mixing and filtering such primary gases;
c) a means of producing CO₂ gas;
d) a means of storing CO₂ gas;
e) a means of mixing the filtered primary gases with the previously produced CO₂ gas in a catalytic reaction at a temperature above 15° C. and below 500° C. and at a pressure equal or higher than 1 bar and lower than 10 bar;
f) a means of conveying such mixture over the surface of a desired catalyst;
g) a means of releasing undesired and unneeded molecules;
h) a means of collecting the final gas formulation with the desired chemical properties;
i) a means of recovering water produced through the process; and
j) a means of recovering any residual CO₂ gas for use in the process in combination with the produced and stored CO₂ gas.

24. The system of claim 23 wherein the means of producing primary gases through water electrolysis receives a water solution from a reservoir

25. The system of claim 24 wherein the means of producing CO₂ is a CO₂ generator.

26. The system of claim 24 wherein the means of producing the primary gases is a electrolytic gas generator that is connected to the reservoir.

27. The system of claim 26 wherein such electrolytic gas generator produces H₂, O₂ and OH gases.

28. The system of claim 23 wherein such filtering cleans the gases produced through electrolysis.

29. The system of claim 23 further comprising means for conveying the produced gas to the filter and means for conveying and regulating the gas flow towards the catalytic reactor.

30. The system of claim 25 wherein such CO₂ generator is powered by an accumulator.

31. The system of claim 32 further comprising means for conveying and regulating the flow of gas to the means for the catalytic reaction.

32. The system of claim 23 wherein CO is also produced with the production of the CO₂.

33. The system of claim 32 wherein such catalytic reaction involves the mixing of the gases produced in the previous stages in the presence of a catalyst material.

34. The system of claim 33 wherein such catalyst material is at least one of the group of elements including Copper, Nickel, Iron, Platinum, Ruthenium, Manganese, Molybdenum, and Cobalt.

35. The system of claim 34 wherein in the desired catalyst material is a combination of such elements.

36. The system of claim 23 wherein such means of collecting the final gas formulation further comprises a gas tank for the accumulation of gases produced in said catalytic reactor.

37. The system of claim 23 wherein the means of recovering water produced through the process further comprises the condensation of water.

38. The system of claim 37 further comprising a means for conveying the condensed water to the reservoir.

39. The system of claim 23 further comprising a programmable logic computer system controlling and adjusting the system and process.

40. The system of claim 39 further comprising means of connecting the programmable logic computer to at least one of a group of the temperature sensors, pressure sensors, control valves and electrical switches.

41. The system of claim 23 wherein the catalytic reaction occurs at a temperature comprised between 15° C. and 500° C. and at a pressure ranging between 1 bar and 20 bar.

42. The system of claim 41 wherein the catalytic reaction produces CH₄, CO₂, H₂, O₂ and H₂O with different mixing ratios.

43. The system of claim 23 further comprising
a) a combustion chamber for the generation of thermal energy;
b) means for conveying and regulating the gas flow towards such combustion chamber;
c) a thermoelectric generator embedded to such combustion chamber for the production of electric energy;
d) means for using the electric energy produced to charge the battery;
e) a heat exchanger to transfer the heat generated in such combustion chamber to a desired element;
f) means for separating CO₂ from exhaust gases;
g) a fan for conveying exhaust gases from such combustion chamber to such means of separating CO₂;
h) a programmable logic computer to control and regulate the operation of the machine and the process;
i) means for detecting the water and the air temperature at the outlet of said heat exchanger and for the regulation of the water or air circulation;
j) means for detecting the temperature of the incoming water and air to said heat exchanger for adjusting the flow of said water or air;
k) means for water or air circulation through said heat exchanger with water or air;
l) means for pushing the fuel gas through the CO₂ separator and towards the exhaust;
m) means for the transport of said recovered CO₂ to the CO₂ generator;
n) means to connect the programmable logic computer to said temperature sensor, said pressure sensor, said control valves and said electric switches.

44. A combustible fuel gas produced through the practice of the method of claim 1.

45. A combustible fuel gas produced through the practice of the system of claim 23.

46. The combustible fuel gas of claim 44 where such gas can be accumulated in a tank and is efficiently burnable to generated heat and power.

47. The combustible fuel gas of claim 46 which can be safely transported substantially used for other gases used at residences.

48. The combustible fuel gas of claim 46 which can be safely used in internal combustion and other engines for vehicles.

49. The combustible fuel gas of claim 45 where such gas can be accumulated in a tank and is efficiently burnable to generated heat and power

50. The combustible fuel gas of claim 49 which can be safely transported substantially used for other gases used at residences.

51. The combustible fuel gas of claim 49 which can be safely used in internal combustion and other engines for vehicles.
